(19) United States
(12) Patent Application Publication
(10) Pub. No.: US 2025/0305111 A1
(43) Pub. Date: Oct. 2, 2025

(54) 193NM FILM WITH LOW LOSS AND HIGH REFLECTIVITY AND ITS PREPARATION METHOD

(71) Applicant: Tongji University, Shanghai (CN)

(72) Inventors: Hongfei JIAO, Shanghai (CN); Xinshang NIU, Shanghai (CN); Yingfu LI, Shanghai (CN); Jinlong ZHANG, Shanghai (CN); Xiaochuan JI, Shanghai (CN); Jingjing XIA, Shanghai (CN); Xinbin CHENG, Shanghai (CN); Zhanshan WANG, Shanghai (CN)

(73) Assignee: Tongji University, Shanghai (CN)

(21) Appl. No.: 18/910,033

(22) Filed: Oct. 9, 2024

(30) Foreign Application Priority Data
Mar. 13, 2024 (CN) 202410284689.9

(51) Int. Cl. C23C 14/06; C23C 14/30; G02B 5/08

(52) U.S. Cl. CPC C23C 14/0694; C23C 14/30; G02B 5/0891

(57) ABSTRACT

The provided is a 193 nm film with low loss and high reflectivity and its preparation method, including a substrate and a film deposited on the substrate; the film structure is Sub/(HL)^{\hat{ }n}/Air, wherein Sub is the substrate of the film element, Air is the outgoing medium air, H and L are the high refractive index material film layer and the low refractive index material film layer with ¼ central wavelength optical thickness respectively, and n is the number of film stacks of high and low refractive index materials. The provided adopts the above-mentioned 193 nm film with low loss and high reflectivity and its preparation method, which can effectively inhibit the crystallization of LaF₃ film in 193 nm high reflective film, thereby reducing the roughness of the reflective film, inhibiting the scattering loss, and improving the reflectivity of the film.

### CROSS-REFERENCE TO THE RELATED APPLICATIONS

This application is based upon and claims priority to Chinese Patent Application No. 202410284689.9, filed on Mar. 13, 2024, the entire contents of which are incorporated herein by reference.

### TECHNICAL FIELD

The invention belongs to the field of optical film technology, which specifically relates to a 193 nm film with low loss and high reflectivity and its preparation method.

### BACKGROUND

In recent years, integrated circuit and chip technology have developed rapidly, they represent the level of national scientific and technological production and have a significant impact on the development of high-tech industry. The lithography system is an important technology for preparing high-precision chip. In the lithography system, the resolution determines the feature size of the transistor, and the exposure wavelength determines the resolution of the lithography, the smaller the exposure wavelength, the higher the resolution. At present, the energy output efficiency of the 193 nm lithography machine is not high enough, the main reason is that there are a large number of optical components before and after the lithography machine optical path and the laser resonator, of which the 193 nm reflective element is the core device.

The ideal reflective element needs to take into account the characteristics of low absorption, low scattering and high spectral efficiency, and the characteristics of high and low refractive index determine the optical property of the reflective element. LaF₃ and AlF₃ are commonly used materials for preparing 193 nm film with low loss and high reflectivity due to their wide band gap and small absorption. Among them, AlF₃ film material has the characteristics of dense amorphous microstructure, low loss, good film quality and not easy to crack. The LaF₃ film material is easy to crystallize, and its surface has a conical columnar structure with high and low fluctuations, so its scattering loss is large. In addition, the surface tensile stress of LaF₃ film prepared by electron beam evaporation and thermal evaporation is large, which makes the reflective film layer easy to crack. Only through process improvement, it is difficult to break through the performance limit of the material itself, which seriously limits the comprehensive performance of the 193 nm reflective film with high reflectivity.

### SUMMARY

The purpose of the invention is to provide a 193 nm film with low loss and high reflectivity and its preparation method, which can effectively inhibit the crystallization of LaF₃ film in 193 nm high reflective film, thereby reducing the roughness of the reflective film, inhibiting the scattering loss, and improving the reflectivity of the film. Moreover, it effectively improves the reflectivity and film quality of 193 nm LaF₃/AlF₃ multilayer high-reflective film prepared by electron beam evaporation. At the same time, it has low production cost and is easy to be popularized, so that it has a wide application prospect in the field of UV lithography.

To achieve the above purpose, the invention provides the 193 nm film with low loss and high reflectivity, including a substrate and a film, the film is deposited on the substrate; a film structure is Sub/(HL)^{\hat{ }n}/Air, wherein Sub is the substrate of a film element, Air is an outgoing medium air, H and L are a high refractive index material film layer and a low refractive index material film layer with ¼ central wavelength optical thickness respectively, and n is a number of film stacks of high and low refractive index materials.

Preferably, a center wavelength of the film is 193 nm; a number of film stacks is 18-30.

Preferably, a material of a substrate is fused silica with a roughness of less than 0.5 nm.

Preferably, the high refractive index material film layer H is a LaF₃-AlF₃ mixed film, and the low refractive index material film layer L is an AlF₃ film.

A preparation method for 193 nm film with low loss and high reflectivity includes the following steps:
S1, selecting an electron beam evaporation deposition equipment and the substrate, and adding a crystal oscillator thickness monitor to symmetrical positions on both sides of a coating cavity of the electron beam evaporation deposition equipment;

S2, preparing the high refractive index material film layer H, setting the LaF₃ side corresponding to a crystal oscillator monitoring rate of 0.7 nm/s, setting the AlF₃ side corresponding to the crystal oscillator monitoring rate of 0.3 nm/s;
Opening LaF₃ side and AlF₃ side baffles at the same time during evaporation, depositing the LaF₃-AlF₃ mixed film by using a dual-source electron beam co-evaporation deposition process, and controlling a film thickness by using a time monitoring.

S3, preparing the low refractive index material film layer L, setting the AlF₃ side corresponding to the crystal oscillator monitoring rate of 0.3 nm/s, and using the crystal oscillator monitoring to control the film thickness;
S4, alternately depositing the high refractive index material film layer H and the low refractive index material film layer L until the film structure is plated.

Preferably, in S1, a spatial position of the crystal oscillator thickness monitor is lower than a workpiece plate.

Preferably, in S2, a physical thickness of the high refractive index material film layer H is expressed as 48.25/(0.7 nH+0.3 nL), wherein nH is a refractive index of LaF₃ and nL is a refractive index of AlF₃.

Preferably, in S3, a physical thickness of the low refractive index material film layer L is expressed as 48.25/n, wherein n is a refractive index of the low refractive index material film layer L.

Preferably, in the dual-source electron beam co-evaporation deposition process, a substrate temperature is 150-250° C., and a vacuum degree is less than 1.8×10⁻⁴ Pa.

The beneficial effects of the invention are as follows:

(1) The lanthanum fluoride/aluminum composite film prepared by the invention has low roughness: when preparing 193 nm LaF₃/AlF₃ multilayer reflective film, 30% AlF₃ is doped into the high refractive index LaF₃ film by dual-source co-evaporation technology to form La_{0.70}Al_{0.30}F₃ mixed film; amorphous AlF₃ occupies many nucleation sites and prevents the formation of crystalline phase. Moreover, the ionic radii of Al and La are different, which hinders the formation of long-range ordered structure, thus effectively inhibiting the crystallization of LaF₃, reducing the volume roughness and interface roughness of LaF₃/AlF₃ multilayer reflective film, and inhibiting the scattering loss of the films.

(2) In this invention, the film absorption is small and the tensile stress is small, the AlF₃ evaporation source is introduced on the other side of the cavity, which is equivalent to ‘doping’ a part of AlF₃ in LaF₃. Because AlF₃ has smaller absorption and wider band gap, the absorption loss of the reflective film is effectively reduced. In addition, the chemical bond strength between aluminum atom and fluorine atom is higher than that of lanthanum atom and fluorine atom, and the tensile stress is smaller, which is equivalent to the introduction of higher energy chemical bond in the composite material. Therefore, the prepared La_{0.70}Al_{0.30}F₃ mixed film has lower tensile stress, which makes the 193 nm reflective film more difficult to crack with the increase of film deposition thickness, and the film quality is better.

(3) The reflective film prepared by the nanocomposite material has a smaller scattering loss and a dense amorphous structure, the reflectivity can reach 98.7%, which is higher than the preparation level of the reflective film in this band in China.

(4) The invention has the advantages of simple and easy operation, strong operability and high efficiency, it will have a wider application in the preparation of low loss laser film.

The following is a further detailed description of the technical scheme of the invention through drawings and embodiments.

### BRIEF DESCRIPTION OF THE DRAWINGS

FIG. 1 shows the atomic force surface topography of La_{0.70}Al_{0.30}F₃/AlF₃ reflective film prepared from the Embodiment 1 of a 193 nm film with low loss and high reflectivity and its preparation method.

FIG. 2 shows the atomic force surface topography of LaF₃/AlF₃ reflective film prepared from the Embodiment 1 of a 193 nm film with low loss and high reflectivity and its preparation method.

FIG. 3 shows the XRD comparison diagram of the La_{0.70}Al_{0.30}F₃/AlF₃ reflective film prepared from the Embodiment 1 of a 193 nm film with low loss and high reflectivity and its preparation method and the LaF₃/AlF₃ reflective film prepared form the Ratio 1.

FIGS. 4A and 4B show the surface microtopography of the La_{0.70}Al_{0.30}F₃/AlF₃ reflective film prepared from the Embodiment 1 of a 193 nm film with low loss and high reflectivity and its preparation method and the LaF₃/AlF₃ reflective film prepared form the Ratio 1.

FIG. 5 shows the reflectance spectrum comparison diagram of the La_{0.70}Al_{0.30}F₃ reflective film prepared from the Embodiment 1 of a 193 nm film with low loss and high reflectivity and its preparation method and the LaF₃/AlF₃ reflective film prepared form the Ratio 1.

### DETAILED DESCRIPTION OF THE EMBODIMENTS

The technical scheme of the invention is further explained below by drawings and embodiments.

Unless otherwise defined, the technical or scientific terms used in the invention shall be those to which the invention belongs.

### Embodiment 1

The invention takes the high reflective film with a center wavelength of 193 nm and an incidence angle of 0° as an example, this embodiment provides a preparation method for a film with low loss and high reflectivity, including the following steps:
S1, the film structure is Sub/(HL)^{\hat{ }25}/Air, the center wavelength is 193 nm;
Selecting the modified OTFC-1300 equipment of Japan, and the substrate material is fused silica with a roughness of less than 0.5 nm and a size of φ30 mm×5 mm.

Adding the crystal oscillator thickness monitor to symmetrical positions on both sides of the coating cavity of the electron beam evaporation deposition equipment, and the spatial position of the crystal oscillator thickness monitor is lower than that of the workpiece plate. By evaporating the film material on the left and right sides, it can be evaporated to the corresponding monitoring points without changing the thickness distribution on the workpiece plate.

S2, preparing the high refractive index material film layer H, setting the LaF₃ side corresponding to the crystal oscillator monitoring rate of 0.7 nm/s, setting the AlF₃ side corresponding to the crystal oscillator monitoring rate of 0.3 nm/s;
Opening LaF₃ side and AlF₃ side baffles at the same time during evaporation, depositing the LaF₃₋AlF₃ mixed film by using the dual-source electron beam co-evaporation deposition process, and controlling the film thickness by using the time monitoring.

The physical thickness of the high refractive index material film layer H is 48.25/(0.7 nH+0.3 nL)=30.5 nm, wherein nH is the refractive index of LaF₃ (1.66) and nL is the refractive index of AlF₃ (1.40).

S3, preparing the low refractive index material film layer L, setting the AlF₃ side corresponding to the crystal oscillator monitoring rate of 0.3 nm/s, and using the crystal oscillator monitoring to control the film thickness;
The physical thickness of the low refractive index material film layer L is 48.25/n=34.4 nm, wherein n is the refractive index of the low refractive index material film layer L (1.40);
S4, when the substrate temperature is 250° C. and the vacuum degree is 1.5×10⁻⁴ Pa, alternately depositing the high refractive index material film layer H and the low refractive index material film layer L until the film structure is plated.

### Ratio 1.

The ratio provides a method for preparing a film with low loss and high reflectivity (existing conventional technology), including the following steps:
S1, the film structure is Sub/(HL)^{\hat{ }25}/Air, the center wavelength is 193 nm;
Selecting the modified OTFC-1300 equipment of Japan, and the substrate material is fused silica with roughness less than 0.5nm and size of φ30 mm×5 mm.

S2, preparing the high refractive index material film layer H, setting the LaF₃ side corresponding to the crystal oscillator monitoring rate of 0.7 nm/s; the physical thickness of the high refractive index material film layer H is 48.25/nH=29 nm, wherein nH is the refractive index of LaF₃ (1.66).

S3, preparing the low refractive index material film layer L, setting the AlF₃ side corresponding to the crystal oscillator monitoring rate of 0.3 nm/s, and using the crystal oscillator monitoring to control the film thickness;
The physical thickness of the low refractive index material film layer L is 48.25/nL=30.36 nm, wherein nL is the refractive index of the low refractive index material film layer L (1.40);
S4, when the substrate temperature is 250° C. and the vacuum degree is 1.5×10⁻⁴ Pa, alternately depositing the high refractive index material film layer H and the low refractive index material film layer L until the film structure is plated.

The La_{0.70}Al_{0.30}F₃AlF₃ film prepared by the Embodiment 1 and the LaF₃/AlF₃ film prepared by the Ratio 1 are tested:

### (1) Surface Topography Test.

Test instrument: Bruker atomic force microscope; scanning range: 1 μm.

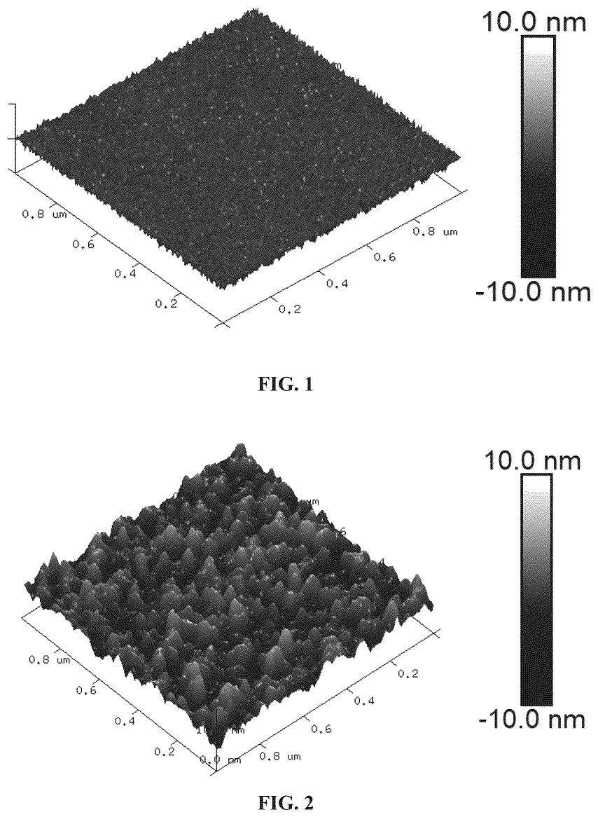

As shown in FIGS. 1-2, the La_{0.70}Al_{0.30}F₃/AlF₃ film prepared by the Embodiment 1 has a smooth surface and its surface roughness is only 1 nm; for the LaF₃/AlF₃ film prepared by the Ratio 1, its surface contains a large number of conical columnar crystal structures, and its surface undulates greatly, besides, the roughness of the surface is as high as 3.09 nm.

This test fully demonstrates that the preparation method of the Embodiment 1 can reduce the bulk roughness and interface roughness of the LaF₃/AlF₃ multilayer reflective film, thereby reducing the scattering loss of the film.

### (2) XRD Test.

Test instrument: X-ray diffractometer, scanning angle: 20-60 degrees.

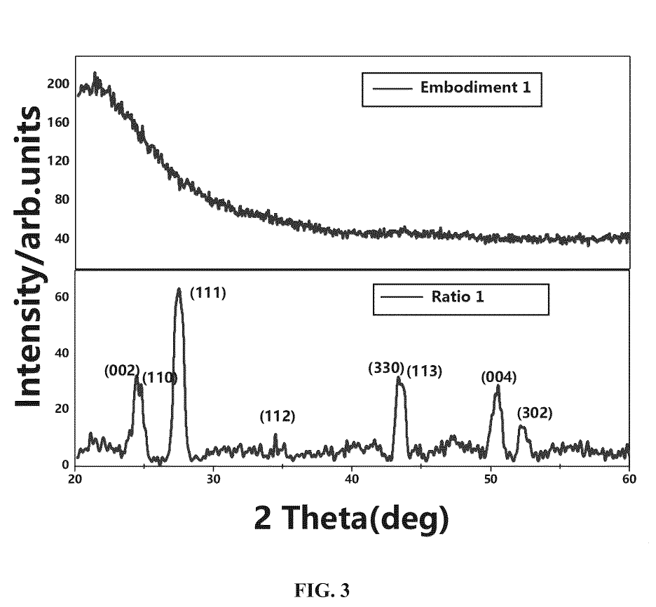

As shown in FIG. 3, according to the ICDD database PDF-06-0318, a series of diffraction peaks including (0, 0, 2), (1, 1, 0), (1, 1, 1), (1, 1, 2), (3, 3, 0), (1, 1, 3), (0, 0, 4) and (3,0, 2) are observed in the XRD crystal phase of the lanthanum fluoride monolayer film prepared by the Ratio 1, which are corresponding to the LaF₃ crystal direction and mainly grow along the (1, 1, 1) crystal direction, the La_{0.70}Al_{0.30}F₃/AlF₃ reflective film prepared in Embodiment 1 has no diffraction peak and the film is amorphous.

The test result fully illustrates that the preparation method of the Embodiment 1 plays an important role in inhibiting the crystallization of the lanthanum fluoride film.

### (3) Microscopic Test of Surface Topography.

Test instrument: Leica differential interference microscope, testing the surface topography of the Embodiment 1 and the Ratio 1.

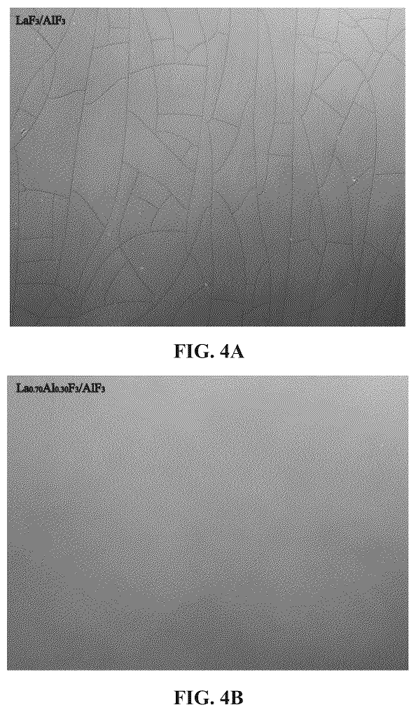

As shown in FIGS. 4A and 4B, the La_{0.70}Al_{0.30}F₃/AlF₃ reflective film in Embodiment 1 has good film forming quality and no obvious surface cracking. However, for the LaF₃/AlF₃ reflective film in the Ratio 1, the surface of the film is densely covered with crack and the film quality is poor.

Because the chemical bond strength between aluminum atom and fluorine atom is higher than that of lanthanum atom and fluorine atom, and the tensile stress is smaller, which is equivalent to the introduction of higher energy chemical bond in La_{0.70}Al_{0.30}F₃, the prepared La_{0.70}Al_{0.30}F₃ mixed film has lower tensile stress, which makes the La_{0.70}Al_{0.30}F₃/AlF₃ reflective film more difficult to crack with the increase of film deposition thickness, and the film quality is better.

### (4) Reflectivity Test.

Test instrument: Agilent cary 7000 spectrophotometer; test angle: 6 degrees; test wavelength: 190-240 nm.

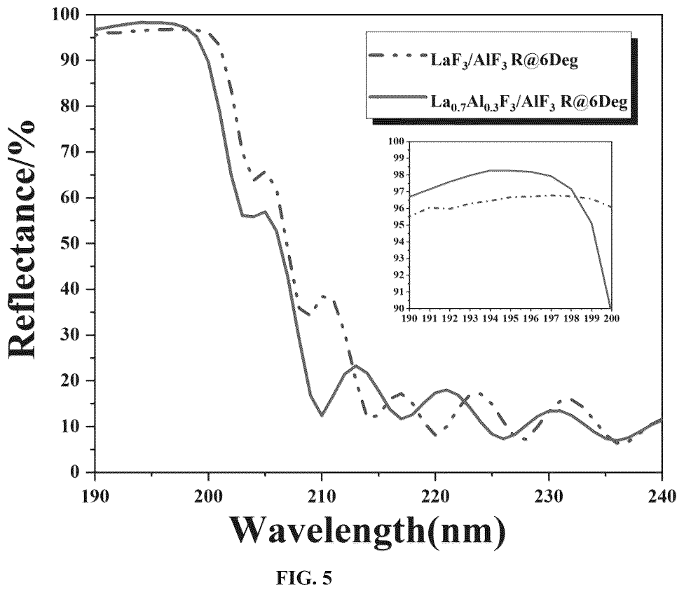

The reflection spectra of the two 193 nm reflectors in Embodiment 1 and Ratio 1 are obtained by spectrophotometer, as shown in FIG. 5, the result show that the maximum reflectivity of the La_{0.70}Al_{0.30}F₃/AlF₃ reflector in Embodiment 1 is 98.7%, and the maximum reflectivity of the LaF₃/AlF₃ reflector in Ratio 1 is 96.2%. Compared with the Ratio 1, the reflectivity of the reflective film of the Embodiment 1 is increased by 2.5%.

Therefore, the invention adopts the above-mentioned 193 nm film with low loss and high reflectivity and its preparation method, which can effectively inhibit the crystallization of LaF₃ film in 193 nm high reflective film, thereby reducing the roughness of the reflective film, inhibiting the scattering loss, and improving the reflectivity of the film; moreover, it effectively improves the reflectivity and film quality of 193 nm LaF₃/AlF₃ multilayer high-reflective film prepared by electron beam evaporation, at the same time, it has low production cost and is easy to be popularized, so that it has a wide application prospect in the field of UV lithography.

Finally, it should be noted that the above embodiments are only used to explain the technical scheme of the invention rather than to restrict it, although the invention is described in detail with reference to the better embodiments, ordinary technicians in this field should understand that they can still modify or replace the technical scheme of the invention, and these modifications or equivalent replacements cannot make the modified technical scheme out of the spirit and scope of the technical scheme of the invention.

What is claimed is:

1. A preparation method for a 193 nm film, comprising a substrate and a film, the film is deposited on the substrate; a film structure is Sub/(HL)^{\hat{ }n}/Air, wherein Sub is a substrate of a film element, Air is an outgoing medium air, H and L are a high refractive index material film layer and a low refractive index material film layer with ¼ central wavelength optical thickness (in nm) respectively, and n is a number of film stacks of high and low refractive index materials;
the high refractive index material film layer His a LaF₃-AlF₃ mixed film, and the low refractive index material film layer L is an AlF₃ film;
wherein the preparation method comprises the following steps:
S1, selecting an electron beam evaporation deposition equipment and the substrate, and adding a crystal oscillator thickness monitor to symmetrical positions on both sides of a coating cavity of the electron beam evaporation deposition equipment;
S2, preparing the high refractive index material film layer H, setting a LaF₃ side corresponding to a crystal oscillator monitoring rate of 0.7 nm/s, setting a first AlF₃ side corresponding to a crystal oscillator monitoring rate of 0.3 nm/s;
opening LaF₃ side and AlF₃ side baffles at the same time during evaporation, depositing the LaF₃-AlF₃ mixed film by using a dual-source electron beam co-evaporation deposition process, and controlling a film thickness by using a time monitoring;
in S2, a physical thickness (in nm) of the high refractive index material film layer H is expressed as 48.25/(0.7 nH+0.3 nL), wherein nH is a refractive index of LaF₃ and nL is a refractive index of AlF₃;
S3, preparing the low refractive index material film layer L, setting a second AlF₃ side corresponding to the crystal oscillator monitoring rate of 0.3 nm/s, and using crystal oscillator monitoring to control the film thickness;
in S3, a physical thickness (in nm) of the low refractive index material film layer L is expressed as 48.25/n, wherein n is a refractive index of the low refractive index material film layer L;
S4, alternately depositing the high refractive index material film layer H and the low refractive index material film layer L until the film structure is plated to obtain a La_{0.70}Al_{0.30}F₃/AlF₃ film, wherein in the dual-source electron beam co-evaporation deposition process, a substrate temperature is 150-250° C., and a vacuum degree is less than 1.8×10⁻⁴ Pa.

2. The preparation method for the 193 nm film according to claim 1, wherein a central wavelength of the film is 193 nm, the number of film stacks is 18-30.

3. The preparation method for the 193 nm film according to claim 1, wherein a substrate material is fused silica, and a roughness is less than 0.5 nm.

4. The preparation method for the 193 nm film according to claim 1, wherein a spatial position of the crystal oscillator thickness monitor is lower than a workpiece plate.

5. (canceled)
